(19) United States
(12) Patent Application Publication
(10) Pub. No.: US 2007/0228434 A1
(43) Pub. Date: Oct. 4, 2007

(54) Semiconductor memory device

(76) Inventor: Yoshiro Shimojo, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/450,458

(22) Filed: Jun. 12, 2006

(30) Foreign Application Priority Data
Mar. 29, 2006 (JP) 2006-092097

(51) Int. Cl. H01L 29/94; H01L 27/108; H01L 29/76; H01L 31/119

(52) U.S. Cl. 257/296

(57) ABSTRACT

A semiconductor memory device including a capacitor array having an effective size smaller than a minimum feature size of lithography is disclosed. According to one aspect of the present invention, it is provided a semiconductor memory device comprising a transistor including a gate electrode formed on a gate insulator on a semiconductor substrate and a plurality of sources/drains disposed in the semiconductor substrate to face each other holding the gate electrode therebetween, a ferroelectric capacitor formed above the transistor and including a lower electrode, a ferroelectric film, and an upper electrode, a first wiring line electrically connected to the lower electrode, and a second wiring line electrically connected to the upper electrode, wherein the ferroelectric capacitor is a staggered-electrode capacitor in which the upper electrode is shifted from the lower electrode and equivalently overlaps with parts of the plurality of lower electrodes.

### CROSS-REFERENCE TO RELATED APPLICATIONS

This application is based upon and claims the benefit of priority from prior Japanese Patent Application No. 2006-092097, filed Mar. 29, 2006, the entire contents of which are incorporated herein by reference.

### BACKGROUND OF THE INVENTION

1. Field of the Invention

The present invention relates to a semiconductor memory device, and more particularly to a semiconductor memory device including a capacitor.

2. Description of the Related Art

Higher integration of a semiconductor device has been accompanied by a progress in miniaturization of elements used for the semiconductor device. The miniaturization of the elements is achieved by reducing a minimum feature size of lithography.

However, current semiconductor devices are not enough to satisfy a demand for miniaturization. For example, as disclosed in Jpn. Pat. Appln, KOKAI Publication No. 2001-257320, in a semiconductor memory device such as a ferroelectric semiconductor memory device, a side face of a capacitor, which serves as an element device, is formed to be inclined. This structure is not suited to miniaturization since an effective area is smaller as compared with an amount of space occupied by the capacitor. A reason for forming such a structure is to prevent an etching problem that is formation of an etching byproduct on the side face of the capacitor when the side face of the capacitor is vertically etched. For example, if the etching byproduct is conductive, the structure allows preventing short-circuiting between upper and lower electrodes of the capacitor. Moreover, even if the side face of the capacitor can be etched to be vertical, its size is limited by the minimum feature size of lithography. Specifically, a capacitor area cannot be set smaller than L², where L is a minimum feature size of lithography.

### BRIEF SUMMARY OF THE INVENTION

According to one aspect of the present invention, it is provided a semiconductor memory device comprising: a transistor including a gate electrode formed on a gate insulator on a semiconductor substrate and a plurality of sources/drains disposed in the semiconductor substrate to face each other holding the gate electrode therebetween; a ferroelectric capacitor formed above the transistor and including a lower electrode, a ferroelectric film, and an upper electrode; a first wiring line electrically connected to the lower electrode; and a second wiring line electrically connected to the upper electrode, wherein the ferroelectric capacitor is a staggered-electrode capacitor in which the upper electrode is shifted from the lower electrode and equivalently overlaps with parts of the plurality of lower electrodes.

According to another aspect of the present invention, it is provided a semiconductor memory device comprising: a plurality of transistors electrically connected in series, each transistor including a gate electrode formed on a gate insulator on a semiconductor substrate and a plurality of sources/drains disposed in the semiconductor substrate to face each other holding the gate electrode therebetween; a plurality of ferroelectric capacitors electrically connected to the transistors in parallel, each capacitor including a lower electrode, a ferroelectric film, and an upper electrode; a first wiring line connected to one end of the plurality of serially connected transistors; and a second wiring line connected to the other end of the plurality of serially connected transistors, wherein the ferroelectric capacitors are staggered-electrode capacitors in which the lower and upper electrodes are square, arranged to be shifted from and overlapped with each other, and equivalently shared with a plurality of ferroelectric capacitors, and a serial connection direction of the transistors is one of diagonal directions of the square lower and upper electrodes.

### BRIEF DESCRIPTION OF THE SEVERAL VIEWS OF THE DRAWING

FIG. 1 is a plan diagram showing an example of a semiconductor memory device including a staggered-electrode capacitor according to a first embodiment of the present invention;

FIGS. 2A to 2C are diagrams showing manners of interconnection between the staggered-electrode capacitor and cross point transistors according to the first embodiment;

FIG. 3 is a sectional diagram showing an example of a sectional structure of the semiconductor memory device including the staggered-electrode capacitor and the cross point transistors according to the first embodiment;

FIG. 4 is a 3-dimensional circuit diagram showing an example of connection between the staggered-electrode capacitor and first and second cross point transistors of the semiconductor memory device shown in FIG. 2A according to the first embodiment;

FIGS. 5A to 5C are process sectional diagrams showing an example of a method of manufacturing the semiconductor memory device of the first embodiment;

FIGS. 6A and 6B are diagrams showing an example of arrangement of a staggered-electrode capacitor and cross point transistors of a semiconductor memory device according to Modification 1; FIG. 6A is a plan diagram, and FIG. 6B is a sectional diagram including first and second cross point transistors cut along a line 6B-6B in FIG. 6A;

FIG. 7 is a sectional diagram showing an example of arrangement of a staggered-electrode capacitor and cross point transistors of a semiconductor memory device according to Modification 2;

FIGS. 8A and 8B are diagrams showing an example of a semiconductor memory device according to a second embodiment of the present invention; FIG. 8A is a plan diagram, and FIG. 8B is a sectional diagram in a chain-direction of serial connection cut along a line 8B-8B in FIG. 8A;

FIGS. 9A to 9C are diagrams showing an example of a semiconductor memory device according to a third embodiment; FIG. 9A is a plan diagram, FIG. 9B is a sectional diagram including a transistor cut along a line 9B-9B in FIG. 9A, and FIG. 9C is a sectional diagram on a bit line BL cut along a line 9C-9C in FIG. 9A;

FIG. 10 is a diagram of capacitance-voltage characteristics of a capacitor showing an example of an operation of the semiconductor memory device of the third embodiment;

FIG. 11 is a diagram showing another example of a semiconductor memory device of the third embodiment;

FIG. 12 is a plan diagram showing a semiconductor memory device according to Modification 3; and

FIG. 13 is a plan diagram showing a semiconductor memory device according to Modification 4.

### DETAILED DESCRIPTION OF THE INVENTION

The embodiments of the present invention will be described with reference to the accompanying drawings. Throughout the drawings, corresponding portions are denoted by corresponding reference numerals. Each of the following embodiments is illustrated as one example, and therefore the present invention can be variously modified and implemented without departing from the spirits of the present invention.

### First Embodiment

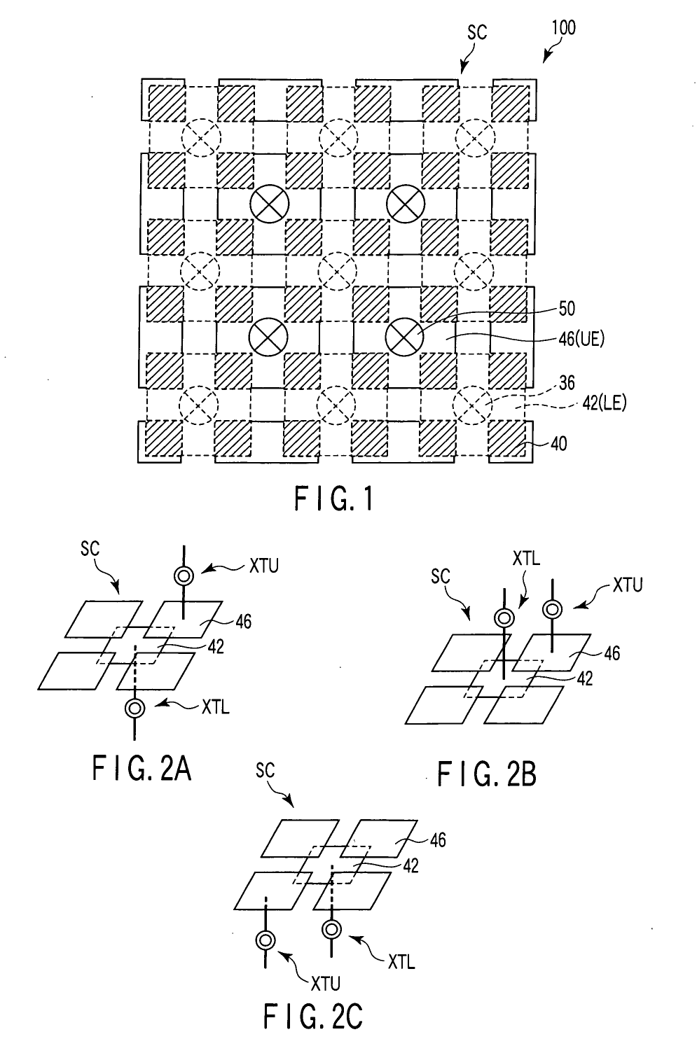

FIG. 1 is a plan diagram showing an example of a ferroelectric semiconductor memory device 100 according to a first embodiment of the present invention. FIG. 1 shows arrangement of an upper and lower electrodes LE(42) and UE(46) of a ferroelectric capacitor 40. The ferroelectric memory device 100 of the embodiment includes a staggered-electrode capacitor SC. Here, the staggered-electrode capacitor SC refers to a ferroelectric capacitor in which an upper electrode UE of the capacitor 40 is shifted in position with respect to a lower electrode LE. In this structure, if sizes of the lower and upper electrodes LE and UE are set to L×L defined by a minimum feature size L of lithography, an amount of the shift is L/2 in vertically and horizontally in the drawing, respectively. Arranging the upper electrode UE in such a manner, each about ¼-electrode area of four upper electrodes UE overlaps on one lower electrode LE. Thus, four capacitors 40 are formed on one lower electrode LE in respective overlapped parts of the lower electrode LE and the upper electrodes UE. In other words, it can be achieved a density four times higher than that of a conventional memory cell. As a result, an area of one capacitor 40 is estimated to be (L/2)×(L/2)=L/4 at a maximum. In reality, considering separation between the electrodes, a space for forming a contact plug connected with each electrode, or the like, an area of one capacitor will be much smaller.

As described above, by forming the staggered-electrode capacitor SC in which the upper and lower electrodes UE(46) and LE(42) of the ferroelectric capacitor 40 are arranged to be shifted, it can be provided a ferroelectric memory device 100 including the capacitor having an effective size smaller than the minimum feature size of lithography. As indicated by circle marks in the example of FIG. 1, contact plugs 36, 50 can be arranged in centers of the electrodes LE, UE, respectively. In the example, the contact plug 36 for the lower electrode LE is connected to a bottom surface of the lower electrode LE, and the contact plug 50 for the upper electrode UE is connected to an upper surface of the upper electrode UE.

To access only one desired capacitor of the semiconductor memory device 100 of the embodiment, each one upper electrode UE and one lower electrode LE must be selected. However, when they are selected by using a conventional planar type transistor, all capacitors connected to one word line are simultaneously selected. In other words, the plurality of capacitors sharing electrodes and connected to one word line substantially become one capacitor, thereby disabling achievement of the high density.

One of the methods of selecting only one capacitor is a method to use cross point transistors. Specifically, a first cross point transistor XTL connected with the lower electrode LE(42) and a second cross point transistor XTU connected with the upper electrode UE(46) are used. Where the cross point transistor XT includes two vertical type transistors VT1, VT2 connected serially, and respective word lines (gate electrodes) WL1, WL2 are arranged to be orthogonal to each other. In the cross point transistor XT, only when both transistors are turned ON the capacitor electrode connected thereto is selected. For details on the vertical transistors constituting the cross point transistor, refer to J. M. Hergenrother et al., “The vertical replacement-gate (VRG) MOSFET”, Solid-State Electronics 46, pp. 937-950, 2002.

FIGS. 2A to 2C show manners of connecting the cross point transistors XT with the staggered-electrode capacitor SC. In FIGS. 2A to 2C, the cross point transistor XT is indicated by a double-circle mark for simplicity. FIG. 2A shows a manner of separately arranging cross point transistors XTs below and above the electrodes 42 and 46. A first cross point transistor XTL is arranged to be connected with the lower electrode 42 below the staggered-electrode capacitor SC, and a second cross point transistor XTU is arranged to be connected with the upper electrode 46 above the same. FIG. 2B or 2C shows alternative manner of arranging both of the first and second cross point transistors XTL, XTU above or below the staggered-electrode capacitor SC. In the case of FIG. 2A, since there is no need to increase an area of the electrode for forming contact plugs, and thus the capacitor can be formed in a minimum size. However, as four layers of vertical transistors VTs are necessary, the number of manufacturing steps is increased. In the case of FIGS. 2B and 2C in which the cross point transistors XTs are arranged only on one side, the electrode area needs to be enlarged by an area of the contact plug and thus an entire capacitor array is enlarged, while only two layers of vertical transistors VTs are necessary.

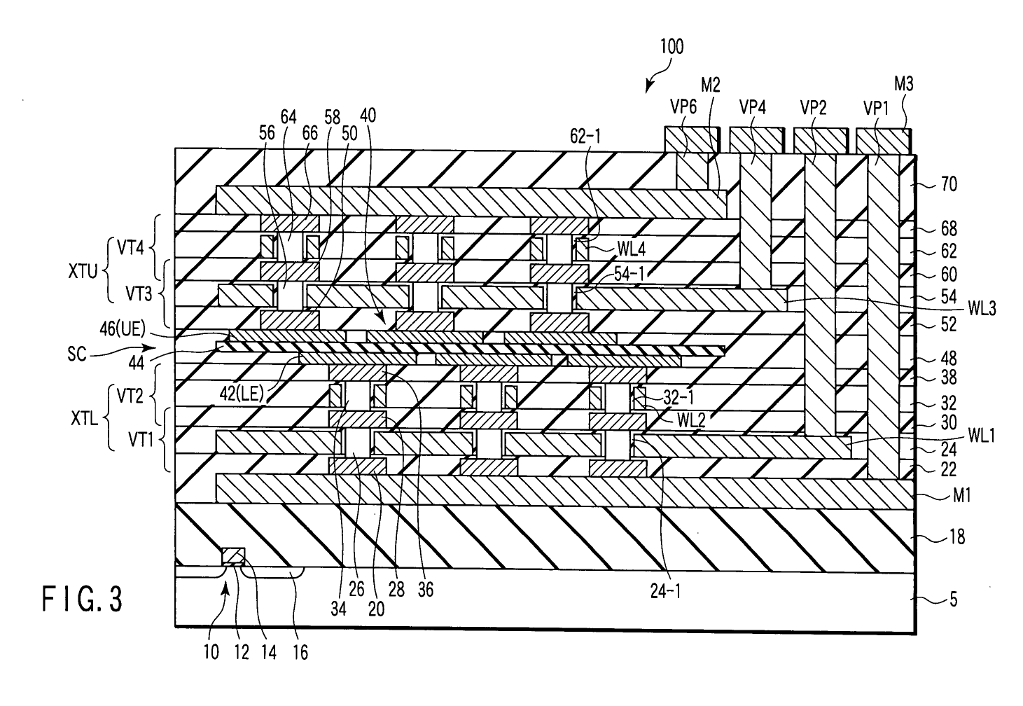

FIG. 3 shows an example of a sectional structure of the semiconductor memory device 100 shown in FIG. 1 including a staggered-electrode capacitor SC. In FIG. 3, the staggered-electrode capacitor SC and cross point transistors XTs are connected in a manner as shown in FIG. 2A. FIG. 3 shows a structure in which the staggered-electrode capacitor SC and the first and second cross point transistors XTL and XTU are formed above a first interlevel insulator 18. The first interlevel insulator 18 is formed to cover a transistor 10 formed on a semiconductor substrate 5. The first and second cross point transistors XTL and XTU include two serially connected vertical transistors VT1, VT2 and VT3, VT4, respectively. It should be noted that as the first and second cross point transistors XTL and XTU are shifted not only in a horizontal direction but also in a cross direction of a paper surface, the section diagram shown in FIG. 3 is not present actually.

A first wiring line M1 is disposed on the first interlevel insulator 18 formed to cover the transistor 10 on the semiconductor substrate 5. The first wiring line M1 serves as a common plate line.

The first cross point transistor XTL is disposed on the first wiring line M1. The first cross point transistor XTL includes serially connected first and second vertical transistors VT1 and VT2. The first vertical transistor VT1 is disposed to connect with the first wiring line M1, and includes a first source/drain 20, a first channel region 26, and a second source/drain 28. A first gate electrode WL1 is disposed on a first gate insulator 24-1 formed around the first channel region 26. The first gate electrode WL1 interconnects a plurality of first gate electrodes arranged in a horizontal direction to serve as a first word line.

The second vertical transistor VT2 is disposed on the first vertical transistor VT1. The second vertical transistor VT2 similarly includes the second source/drain 28, a second channel region 34, a third source/drain 36, a second gate insulator 32-1, and a second gate electrode WL2. The second gate electrode WL2 is disposed in a direction orthogonal to the first gate electrode WL1, and arranged to extend in a direction vertical to the paper surface. The second gate electrode WL2 serves as a second word line. The second source/drain 28 is shared with the first and second vertical transistors VT1 and VT2. The third source/drain 36 also serves as a contact plug to connect with the lower electrode 42 of the staggered-electrode capacitor SC formed thereon.

The staggered-electrode capacitor SC is disposed on the first cross point transistor XTL. The staggered-electrode capacitor SC includes a lower electrode 42, a ferroelectric film 44, and an upper electrode 46. It is presumed here that each of the lower and upper electrodes 42 and 46 is patterned in a square having its one side length set equal to a minimum feature size L of lithography. The lower electrode 42 is connected with the third source/drain 36 of the first cross point transistor XTL. The upper electrode 46 is formed to be shifted by nearly L/2 not only in the horizontal direction but also in the cross direction to the paper surface. One ferroelectric capacitor 40 is formed in each of overlapped parts of the lower and upper electrodes 42 and 46.

The second cross point transistor XTU is disposed on the staggered-electrode capacitor SC. The second cross point transistor XTU includes two serially connected vertical transistors VT3 and VT4. The vertical transistors VT3 and VT4 are similar to the vertical transistors VT1 and VT2, and thus description thereof will be omitted. A fourth source/drain 50 of the second cross point transistor XTU is connected with the upper electrode 46 of the staggered-electrode capacitor SC. Accordingly, the first and second cross point transistors XTL and XTU are arranged in positions shifted from each other by nearly L/2 in the horizontal and the cross directions of the paper surface.

A second wiring line M2 is disposed on the second cross point transistor XTU. The second wiring line M2 is connected with a sixth source/drain 66 to serve as a bit line. In this case, the first and second wiring lines M1 and M2 do not need to be formed in a line, but they can be formed in a plane. The wiring lines M1, M2 and the gate electrodes (word lines) WL1, WL2, WL3, and WL4 are connected with a third wiring line M3 through respective contact plugs VPx.

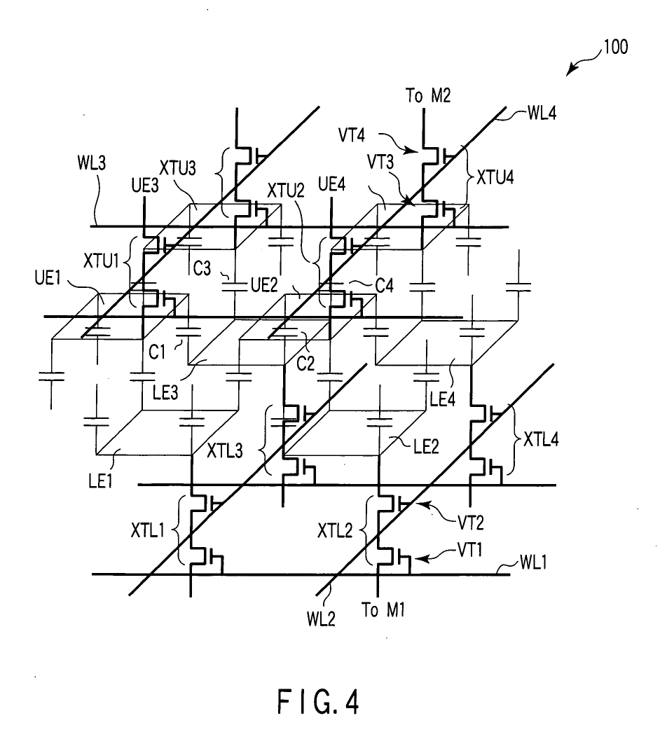

FIG. 4 is a 3-dimensional circuit diagram showing an example of connection between the staggered-electrode capacitor SC and the first and second cross point transistors XTL, XTU arranged as shown in FIG. 2A. The first cross point transistor XTL having the two vertical transistors VT1, VT2 serially connected thereto is arranged below the staggered-electrode capacitor SC to be connected with the lower electrode LE(42). The second cross point transistor XTU is arranged above the capacitor SC to be connected with the upper electrode UE(46). Four lower electrodes LE1 to LE4 are shown, and each of the first cross point transistors XTL1 to XTL4 is connected with corresponding one of the lower electrodes. For example, four capacitors C1 to C4 are disposed on a lower electrode LE3. Each of the capacitors C1 to C4 is connected with corresponding upper electrodes UE1 to UE4. Four capacitors are also disposed in each upper electrode. The capacitors on one upper electrode are connected with different lower electrodes. Each of upper electrodes UE1 to UE4 is connected with corresponding second cross point transistors XTU1 to XTU4.

Among the four capacitors C1 to C4 on the lower electrode LE3, for example, the capacitor C1 is connected with the first cross point transistor XTL3 through the lower electrode LE3, and with the second cross point transistor XTU1 through the upper electrode UE1. Similarly, the capacitor C2 is connected with the second cross point transistor XTU2 through the upper electrode UE4, the capacitor C3 is connected with the second cross point transistor XTU3 through the upper electrode UE3, and the capacitor C4 is connected with the second cross point transistor XTU4 through the upper electrode UE4. Accordingly, for example, if the first cross point transistors XTL3 and the second cross point transistors XTU2 are selected, the capacitor C2 alone can be selected, and other capacitors are not selected.

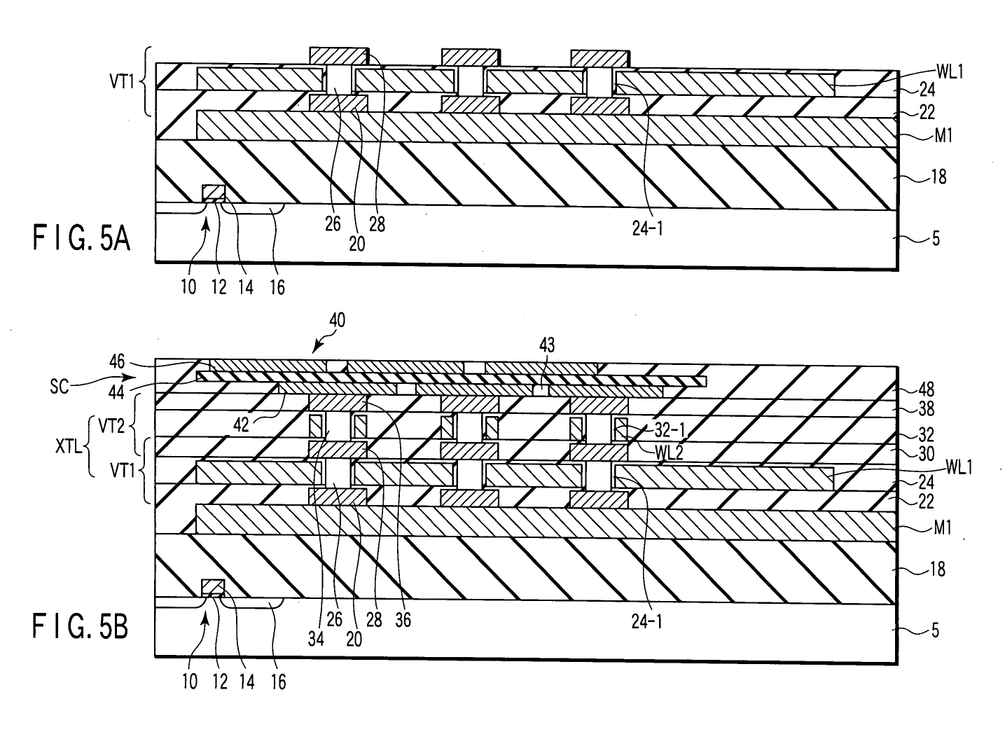

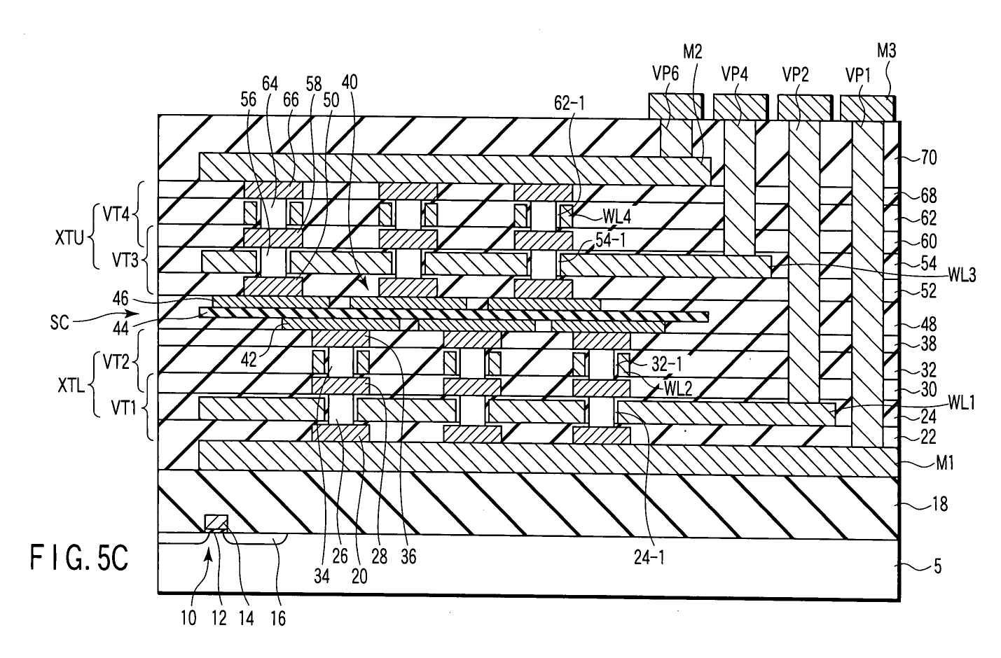

Next, an example of a method of manufacturing the semiconductor memory device 100 shown in FIGS. 1 and 3 will be described by referring to process cross sectional views shown in FIGS. 5A to 5C. The manufacturing method of the first cross point transistor XTL, the staggered-electrode capacitor, and the second cross point transistor XTU, which are directly related to the staggered-electrode capacitor SC, will be described.

(1) Referring to FIG. 5A, a transistor 10 includes a gate electrode 14 formed on a gate insulator 12 on a semiconductor substrate 5, e.g., a silicon substrate, and sources/drains 16 formed in the semiconductor substrate 5 and disposed to face each other holding the gate electrode 14 in-between. A first wiring line M1 is formed on the first interlevel insulator 18 formed to cover the transistor 10. As the first interlevel insulator 18, for example, a silicon oxide film (SiO₂ film) formed by chemical vapor deposition (CVD) can be used. As the first wiring line M1, for example, aluminum (Al) or tungsten (W) can be used. The first wiring line M1 serves as a common plate line of the staggered-electrode capacitor SC.

(2) Next, the first cross point transistor XTL is formed on the first wiring line M1. First, a first semiconductor layer 20 is deposited on an entire surface to cover the first wiring line M1. For the first semiconductor layer 20, for example, n-type silicon doped with a high concentration of phosphorus (P) or arsenic (As) can be used, and it can be formed by CVD. The first semiconductor layer 20 is patterned by lithography and etching to form a first source/drain 20 connected with the first wiring line M1.

(3) A second interlevel insulator 22 is deposited on an entire surface to cover the first source/drain 20, and a surface of the second interlevel insulator 22 is planarized by, e.g., chemical mechanical polishing (CMP). In the planarization, the second interlevel insulator 22 is left thin on the first source/drain 20 to prevent exposure of the first source/drain 20. For the second interlevel insulator 22, for example, a SiO₂ film formed by plasma CVD can be used.

(4) A conductive material which becomes a gate electrode is deposited on an entire surface of the second interlevel insulator 22, and patterned to form a first gate electrode WL1. For the conductive material, for example, aluminum, tungsten, or silicon doped with a high concentration of phosphorus or arsenic can be used. During the patterning, an opening is additionally formed nearly in a center position on the first source/drain 20 to pierce through the first gate electrode WL1. The opening is formed within the first gate electrode WL1 width to prevent cutting it.

(5) A third interlevel insulator 24 is deposited to cover the first gate electrode WL1 and to fill the opening, and a surface of the third interlevel insulator 24 is planarized by, e.g., CMP. In the planarization, the third interlevel insulator 24 is left thin on the first gate electrode WL1 to prevent exposure of the first gate electrode WL1. Then, a second opening which reaches the first source/drain 20 is formed in the opening by, e.g., reactive ion etching (RIE). In the etching, a third interlevel insulator 24-1 is left thin on the side face of the first gate electrode WL1. This third interlevel insulator 24-1 becomes a gate insulator of the first vertical transistor VT1.

(6) A second semiconductor layer 26 is formed to fill the second opening by, e.g., CVD. The second semiconductor layer 26 formed on the third interlevel insulator 24 is removed by, e.g., CMP. The second semiconductor layer 26 has conductivity different from that of the first semiconductor layer 20 and is p-type silicon doped with boron B, for example. In this way, a first channel region 26 of the first vertical transistor VT1 is formed.

(7) A third semiconductor layer 28 is formed on an entire surface to cover the third interlevel insulator 24 and the first channel region 26. For the third semiconductor layer 28, as in the case of the first semiconductor layer 20, for example, n-type silicon doped with a high concentration of phosphorus (P) or arsenic (As) can be used. The third semiconductor layer 28 is patterned to form a second source/drain 28 on the first channel region 26. Accordingly, the first vertical transistor VT1 of the structure shown in FIG. 5A is formed.

(8) Referring to FIG. 5B, a second vertical transistor VT2 is formed on the first vertical transistor VT1. The second source/drain 28 of the first vertical transistor VT1 is shared with the second vertical transistor VT2 as a lower source/drain thereof. Thus, for a forming process of the second vertical transistor VT2, the process from the step (3) of forming an interlevel insulator to the step (7) of forming a source/drain is repeated. In this way, as shown in FIG. 5B, the second vertical transistor VT2 that includes the second source/drain 28, a second channel region 34, a third source/drain 36, and a second gate electrode WL2 is formed. In this case, the second gate electrode WL2 is formed to extend in a direction orthogonal to the first gate electrode WL1 (a direction vertical to the paper surface in the drawing).

Subsequently, a sixth interlevel insulator 38 is formed to cover the third source/drain 36, and the sixth interlevel insulator 38 is planarized by, e.g., CMP, using the third source/drain 36 as a stopper.

Accordingly, the first cross point transistor XTL that includes the first and second vertical transistors VT1, VT2 is formed.

(9) Next, the staggered-electrode capacitor SC is formed on the first cross point transistor XTL.

A lower electrode material 42 of a ferroelectric capacitor is deposited on an entire surface to cover the sixth interlevel insulator 38 and the third source/drain 36. For the lower electrode material, for example, titanium/aluminum nitride (TiAlN), strontium/ruthenium oxide (SrRuO3), or platinum (Pt) can be used. The lower electrode material 42 is patterned to form a lower electrode 42 (LE) to be connected with the third source/drain 36. A space between the lower electrodes 42 can be planarized by an interlevel insulator 43 such as a SiO₂ film, if necessary.

(10) A ferroelectric film 44 and an upper electrode material 46 are sequentially deposited on the lower electrode 42. For the ferroelectric film 44, a metal oxide having a perovskite structure such as lead/zirconium titanate (PZT) or strontium/bismuth tantalite (SBT) can be used. For the upper electrode material 46, the same material as that of the lower electrode 42 can be used.

The upper electrode material 46 is patterned to form an upper electrode 46. As shown in FIG. 1, the patterning is carried out by shifting in horizontal and cross directions by one half of a pitch of the lower electrode 42 so that four corners of the upper electrode 46 can be equivalently overlapped on the four lower electrodes 42. Each overlapped part of the upper and lower electrodes 46 and 42 becomes one ferroelectric capacitor 40.

Then, a seventh interlevel insulator 48 is formed on an entire surface, and planarized by, e.g., CMP, to form the staggered-electrode capacitor SC shown in FIG. 5B.

(11) Referring to FIG. 5C, a second cross point transistor XTU that includes third and fourth vertical transistors VT3 and VT4 is formed on the staggered-electrode capacitor SC. A method of forming the second cross point transistor XTU is similar to that of the first cross point transistor XTL, and thus description thereof will be omitted.

The third vertical transistor VT3 includes a fourth source/drain 50 connected with the upper electrode 46 of the staggered-electrode capacitor SC, a third channel region 56, a fifth source/drain 58, and a third gate electrode WL3. The fourth vertical transistor VT4 includes the fifth source/drain 58, a fourth channel region 64, a sixth source/drain 66, and a fourth gate electrode WL4. The fifth source/drain 58 is shared with the third and fourth vertical transistors VT3, VT4. The sixth source/drain 66 also serves as a contact plug connected with a second wiring line M2 to be formed thereon. The third and fourth gate electrodes WL3 and WL4 are disposed in directions orthogonal to each other.

(12) The second wiring line M2 connected with the sixth source/drain 66 is formed on the second cross point transistor XTU. Since the second wiring line M2 serves as a common bit line, patterning it into a line pattern is not always necessary, and thus it can be formed in a plane pattern. An interlevel insulator 70 is deposited to cover the second wiring line M2, and planarized by, e.g., CMP. Contact plugs VPx each reaching one of the gate electrodes WL1 to WL4 or the wiring lines M1, M2 are formed in a plurality of interlevel insulators. Further, a third wiring line M3 to be connected with each contact plug VPx is formed on the interlevel insulator 70.

Thus, it can be formed the staggered-electrode capacitor SC which includes the cross point transistors XTL, XTU according to the embodiment shown in FIG. 5C.

In the case of the staggered-electrode capacitor of the embodiment, the four capacitors share one electrode. Accordingly, as a voltage is applied to the capacitors connected with the same electrode of the selected capacitor, it needs to pay attention to prevent inversely polarizing a ferroelectric film if the present invention is used in a ferroelectric memory device.

According to the embodiment, the staggered-electrode capacitor is formed by shifting the upper electrode from the lower electrode in the ferroelectric capacitor. By forming capacitors in the staggered-electrode capacitors, it can be formed a capacitor array having an effective size smaller than a size defined by a minimum feature size of lithography.

Hence, a semiconductor memory device that allows a higher packing density of capacitors can be provided.

(Modification 1)

The first embodiment is directed to the case of arranging the cross point transistors XTs above and below the capacitor as shown in FIG. 2A among the three types of arrangements of the staggered-electrode capacitor SC and the cross point transistors XTs shown in FIGS. 2A to 2C. Modification 1 is directed to a semiconductor memory device 110 in which a first cross point transistor XTL connected with a lower electrode 42 and a second cross point transistor XTU connected with an upper electrode 46 are formed above a staggered-electrode capacitor SC by using the same transistor layers, as shown in FIG. 2B. In the semiconductor memory device 110, both the first and second cross point transistors XTL, XTU can be formed by using two transistor layers. Thus, its manufacturing process can be simplified.

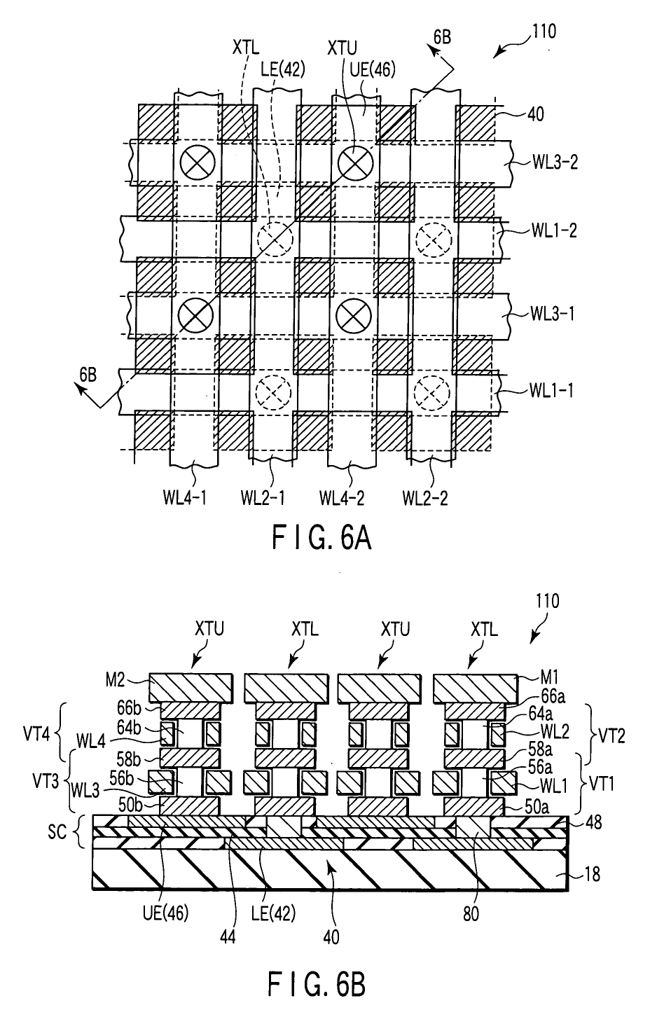

FIGS. 6A and 6B show arrangement of the staggered-electrode capacitor SC and the cross point transistors XT in the semiconductor memory device 110 of the Modification. FIG. 6A is a plan diagram, and FIG. 6B is a sectional diagram in a diagonal direction including the first and second cross point transistors XTL, XTU cut along the line 6B-6B in FIG. 6A. In the drawings, interlevel insulators formed in the transistor layer are omitted.

In FIG. 6A, positions of the first and second cross point transistors XTL, XTU are representatively indicated by circles at positions of contacts to electrodes, and sources/drains are omitted. In the drawing, a lower electrode LE(42) is indicated by a broken line, and an upper electrode UE(46) is indicated by a solid line. One ferroelectric capacitor 40 is formed in an overlapped part (hatched part) of the lower and upper electrodes 42 and 46.

According to the Modification, a staggered-electrode capacitor SC that includes a lower electrode 42, a ferroelectric film 44, and an upper electrode 46 is formed on a first interlevel insulator 18. After the staggered-electrode capacitor SC is planarized by an interlevel insulator 48, a contact plug 80 to be connected with a center of the lower electrode 42 is disposed in the interlevel insulator 48 and the ferroelectric film 44. A first cross point transistor XTL connected with the lower electrode 42 is formed on the contact plug 80. The first cross point transistor XTL includes first and second vertical transistors VT1 and VT2. A first wiring line M1 (plate line) connected with a third source/drain 66a of the second vertical transistor VT2 is disposed on the first cross point transistor XTL. As in the case of the first embodiment, a second cross point transistor XTU that includes third and fourth vertical transistors VT3 and VT4 is formed on the upper electrode 46. A second wiring line M2 (bit line) connected with a sixth source/drain 66b of the fourth vertical transistor VT4 is disposed on the second cross point transistor XTU.

The first and third vertical transistors VT1 and VT3 are formed in the same first transistor layers 50, 56 and 58, and similarly the second and fourth vertical transistors VT2 and VT4 are formed in the same second transistor layers 58, 64 and 66. As shown in FIG. 6A, a first gate electrode WL1 of the first vertical transistor VT1 and a third gate electrode WL3 of the third vertical transistor VT3 are formed in the same wiring layer, but they do not intersect each other because these wiring lines are parallel and shifted from each other by a ½ pitch of the wiring lines. Similarly, a second gate electrode WL2 of the second vertical transistor VT2 and a fourth gate electrode WL4 of the fourth vertical transistor VT4 do not intersect each other.

A case in which no contact plug for connection to the upper electrode 46 is formed is shown. It should be understood, however, that contact plugs could be formed.

(Modification 2)

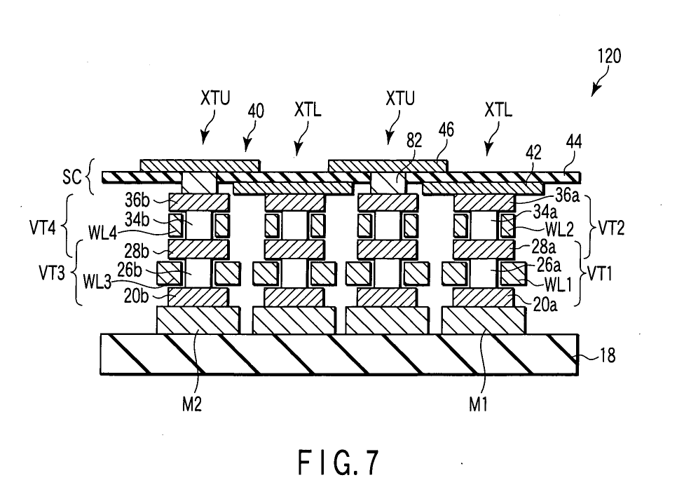

A semiconductor memory device 120 of Modification 2 of the first embodiment employs a structure in which a staggered-electrode capacitor SC is formed on first and second cross point transistors XTL, XTU, as shown in FIG. 2C. As shown in FIG. 7, the semiconductor memory device 120 of the Modification has an upside-down structure of the capacitor and cross point transistors to those of the semiconductor memory device 110 shown in FIGS. 6A and 6B, and thus detailed description thereof will be omitted.

In the semiconductor memory device 120 of the Modification, a process of forming the staggered-electrode capacitor SC on the first and second cross point transistors XTL, XTU is almost similar to that of the first embodiment. However, major differences are; (1) disposing first and second wiring lines M1, M2 on a first interlevel insulator 18, and (2) forming a contact plug 82 connecting the second cross point transistor XTU with an upper electrode 46 and piercing through a ferroelectric film 44 after forming the ferroelectric film 44 on a lower electrode 42.

### Second Embodiment

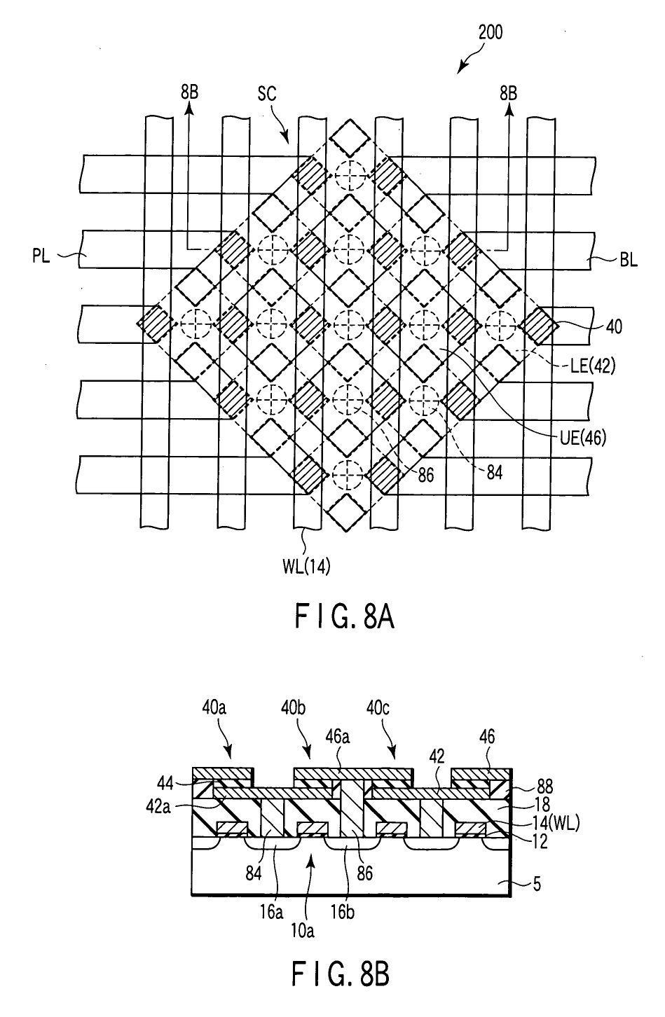

A semiconductor memory device 200 according to a second embodiment of the present invention has a chain type memory cell comprising a staggered-electrode capacitor SC. An example of the semiconductor memory cell 200 of the embodiment will be described by referring to FIGS. 8A and 8B. FIG. 8A is a plan diagram, and FIG. 8B is a sectional diagram in a serially connected chain-direction cut along a line 8B-8B in FIG. 8A.

In the chain type memory cell, a capacitor 40 and a MOS transistor 10 are electrically connected in parallel. For the capacitor 40, for example, a ferroelectric capacitor can be used. According to the embodiment, as shown in FIG. 8B, two capacitors 40a, 40b are formed on one lower electrode 42a. For example, the lower electrode 42a is connected with one source/drain 16a of a MOS transistor 10a through a first contact plug 84. An upper electrode 46a is formed by being shifted from the lower electrode 42 by a ½ pitch, and connected with two capacitors 40b, 40c. The upper electrode 46a is connected with the other source/drain 16b of the MOS transistor 10a through a second contact plug 86. Further, as shown in FIG. 8A, a direction of one side of the square capacitor electrodes 42, 46 and a chain connection direction make an angle of 45°, i.e., the capacitors are serially connected in one diagonal direction of the capacitor electrodes 42, 46. Accordingly, a space for forming contact plugs 84, 86 can be effectively increased by 2^{1/2}, and a process margin for forming the second contact plug 86 can be increased. Thus, by setting process margins to be the same, miniaturization could be achieved by a corresponding amount. A gate electrode 14 of the MOS transistor 10 connects gate electrodes 14 of a plurality of MOS transistors 10 and serves as a word line WL.

The semiconductor memory device 200 that includes the staggered-electrode capacitor SC of the embodiment can be manufactured by a conventional manufacturing method. An example of the manufacturing method will be briefly described by referring to FIG. 8B.

A gate insulator 12 and a gate electrode material 14 are formed on a semiconductor substrate 5, e.g., a silicon substrate, and patterned into a gate electrode 14 by lithography and etching. Using the gate electrode 14 as a mask, for example, arsenic (As) is ion-implanted to the semiconductor substrate 5 to form a source/drain 16. Accordingly, the MOS transistor 10 is formed. The MOS transistor 10 is covered with a first interlevel insulator 18 to be planarized. A first contact plug 84 that reaches one source/drain 16a of the MOS transistor 10a is formed in the first interlevel insulator 18.

A lower electrode 42 of a staggered-electrode capacitor SC is formed on the first contact plug 84. As shown in FIG. 8A, one side of the lower electrode 42 is formed to be oblique by 45° to a chain direction of a memory cell, i.e., a serial connection direction. One side size of the lower electrode can be patterned to a minimum feature size of lithography. A dielectric film 44 such as a ferroelectric film is deposited on an entire surface and patterned into a capacitor shape. An interlevel insulator 88 is deposited on an entire surface, and then planarized. This planarization can be carried out before the dielectric film 44 is deposited. In addition, it may be allowed that the dielectric film 44 is not patterned. A second contact plug 86 that reaches the other source/drain 16b of the MOS transistor 10a is formed in the interlevel insulator 88 and the first interlevel insulator 18. An upper electrode 46 is formed to be connected with the second contact plug 86. The upper electrode 46 is formed by being shifted to the lower electrodes 42 by a ½ pitch both in longitudinal and horizontal directions to be equally overlapped on four lower electrodes 42. Accordingly, the semiconductor memory device 200 that includes the staggered-electrode capacitor SC shown in FIG. 8B can be formed.

As described above, by forming the capacitor electrodes 42, 46 oblique to the chain direction of the memory cell by 45°, the first and second contact plugs 84, 86 can be arranged in the diagonal direction of the capacitor electrodes 42, 46. Thus, an area for forming the second contact plug 86 can be effectively increased by 2^{1/2}, and a margin for forming the second contact plug 86 can be increased.

Furthermore, according to the embodiment, by forming the staggered-electrode capacitor in which the upper electrode of the ferroelectric capacitor is formed by being shifted from the lower electrode, it can be formed a capacitor array having an effective size smaller than the minimum feature size of lithography. Thus, a semiconductor memory device that enables to achieve a higher packing density of a capacitor can be provided.

### Third Embodiment

A semiconductor memory device according to a third embodiment of the present invention includes a ferroelectric capacitor having a hexagonal lower electrode and is a capacitor on bit line (COB) type semiconductor memory device. This structure enables to achieve a higher packing density of the semiconductor memory device. When hexagons are closely packed, each center thereof is shifted by a ½ pitch in both horizontal and longitudinal directions. The embodiment provides a structure suited to an operation in a 2 transistor-2 capacitor (2T-2C) mode. However, the device can also be operated in a 1 transistor-1 capacitor (1T-1T) mode.

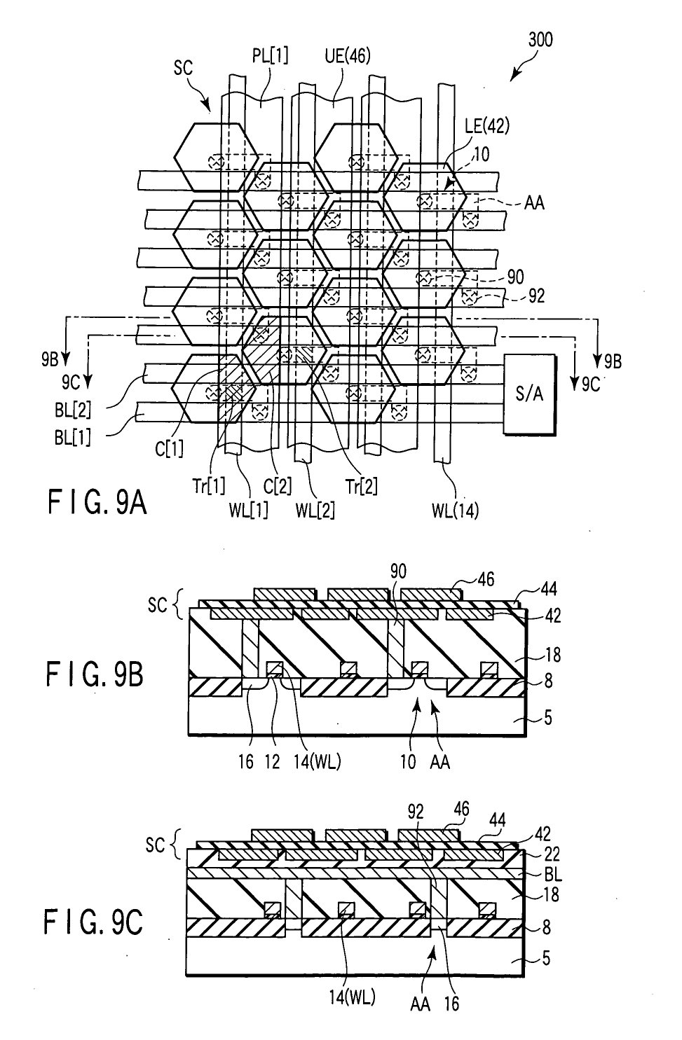

FIGS. 9A to 9C show an example of a structure of the semiconductor memory device 300 of the embodiment. FIG. 9A is a plan diagram, FIG. 9B is a sectional diagram including a transistor cut along a line 9B-9B in FIG. 9A, and FIG. 9C is a sectional diagram on a bit line BL cut along a line 9C-9C in FIG. 9A.

The semiconductor memory device 300 of the embodiment includes a MOS transistor Tr(10), a ferroelectric capacitor C(40), a word line WL, a bit line BL, and a plate line PL. The ferroelectric capacitor 40 of the embodiment has a lower electrode 42 formed into a hexagonal planar shape, and is arranged to be closely packed. The MOS transistor 10 is formed on a semiconductor substrate 5. A gate electrode 14 of the MOS transistor 10 serves as a word line WL by interconnecting gate electrodes of a plurality of MOS transistors 10 arrayed in a longitudinal direction of FIG. 9A. An active area AA for connecting contact plugs 90 and 92 is formed into an L shape in the semiconductor substrate 5, and indicated by a broken line in FIG. 9A. An intersection area between the active area AA and the word line WL becomes a channel region of the MOS transistor 10. The bit line BL is arranged to extend in a horizontal direction of FIG. 9A orthogonal to the word line WL, and connected to one source/drain 16 of the MOS transistor 10 through the contact plug 92. The other source/drain 16 is connected to the lower electrode 42 through the contact plug 90. The ferroelectric capacitor 40 includes a hexagonal lower electrode 42, a ferroelectric film 44, and an upper electrode 46. The upper electrode 46 is arranged to extend in the direction of the word line WL so that it can be overlapped on nearly halves of two rows of lower electrodes 42 arrayed in the direction of the word line WL, and to serve as a common plate line PL. Accordingly, two ferroelectric capacitors 40 are formed on one lower electrode 42, and one ferroelectric capacitor 40 has an area nearly one half of the lower electrode 42. A first contact plug 90 connected with the lower electrode 42 and a second contact plug 92 connected with a bit line BL cannot be formed on the same section parallel to the bit line BL. Hence, the active area AA is formed into the L shape indicated by the broken line in FIG. 9A.

Next, an operation of the ferroelectric memory device 300 of the embodiment will be described.

A) 2T-2C Operation

Consideration will be given to a 2T-2C memory cell constituted of two transistors Tr[1], Tr[2] and two ferroelectric capacitors C[1], C[2], indicated by hatched lines in FIG. 9A. The two transistors Tr[1], Tr[2] are controlled by word lines WL[1], WL[2], respectively. One source/drain of each of the transistors Tr[1], Tr[2] is connected with each of the bit lines BL[1], BL[2]. Upper electrodes of the two ferroelectric capacitors C[1], C[2] are connected in common to a plate line PL[1].

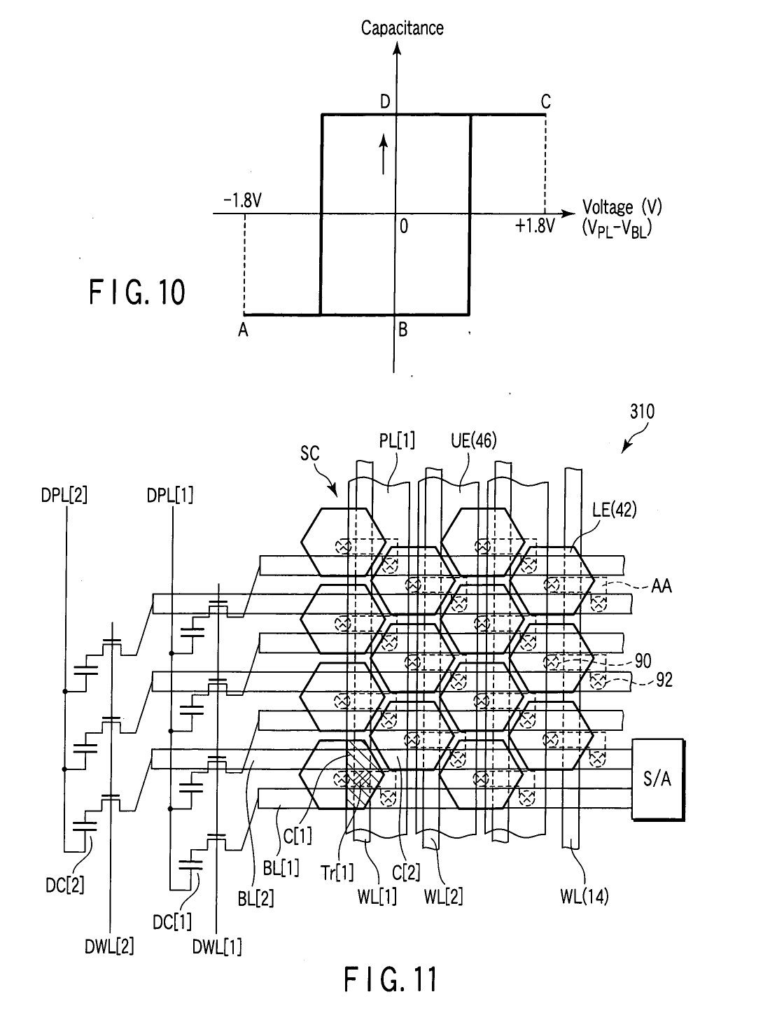

Each of the ferroelectric capacitors C[1], C[2] has capacitance-voltage characteristics shown in FIG. 10, and exhibit similar hysteresis characteristics. It is presumed that the ferroelectric capacitor is polarized in a positive direction indicated by an upward arrow in FIG. 10 when a plate line voltage VPL is larger than a bit line voltage VBL.

A case of writing from a state of nothing written in the ferroelectric capacitor (point 0 in FIG. 10) will be described.

First, the word lines WL[1], WL[2] are set “High”, other word lines WLs are set “Low”, and all plate lines PLs other than the plate line PL[1] are set to floating.

1) When the BL[1] is set to 0 V, the BL[2] is set to 1.8 V, and the PL[1] is set to 0 V, a potential difference −1.8 V is applied to the C[2], and the C[2] is polarized in a negative direction (point A in FIG. 10). However, the C[1] is not changed since no potential difference is applied.

2) When the PL[1] is set to 1.8 V while the BL[1], BL[2] are kept at potentials as they are, a potential difference +1.8 V is applied to the C[1], and the C[1] is polarized in a positive direction (point C). At this potential, as a potential difference of the C[2] is 0 V, the C[2] holds polarization of the negative direction (point B).

3) In this state, all the potentials are set to 0 V (BL[1]=BL[2]=PL[1]=WL[1]=WL[2]=0 V). In other words, when power is turned OFF, the C[1] and the C[2] are written in opposite directions, i.e., the C[1] is written in the positive direction (point D) and the C[2] is written in the negative direction (point B).

Next, a case of reading will be described. For initial setting, as in the case of the writing, the WL[1], WL[2] are set “High”, the other WLs are set “Low”, and all the PLs other than the PL[1] are set to floating.

1) When the BL[1] and BL[2] are set to 0 V, and the PL[1] is set to 1.8 V, as a potential difference of the C[1] is +1.8 V, the C[1] is changed from the point D to the point C, but its positive polarized state is not changed. As a potential difference of the C[2] is +1.8 V, the C[2] is changed from the point B to the point C, and its polarized state is changed from negative to positive. As a result, a plenty of charges are discharged from the C[2]. This is detected by a sense amplifier (S/A) connected to the BL[1] and BL[2]. Thus, destructive reading is carried out.

2) Next, to restore the destroyed data, the BL[1] and BL[2] are returned to original states by a flip flop in the S/A, i.e., the BL[1] is returned to 0 V, and the BL[2] is returned to 1.8 V, and the PL[1] is returned to 0 V. Thus, as a potential difference of the C[2] becomes −1.8 V, the C[2] is changed from the point C to the point A to return to the initial polarized state of the negative direction. As a potential difference of the C[1] is 0 V, the C[1] returns to the point D, but the polarized state is not changed from positive. In other words, rewriting is carried out.

In both of the writing and reading cases, the WL[1] and WL[2] operate in the same manner. In other words, they can be made common, and its example will be described later in Modification 3.

B) 1T-1C Operation

When the ferroelectric semiconductor device shown in FIGS. 9A to 9C is operated in the 1T-1C mode, a dummy capacitor DC is used as shown in a semiconductor memory device 310 in FIG. 11. The dummy capacitor DC is connected to an end of the bit line BL opposite to the S/A. The dummy capacitor DC does not need to be a ferroelectric capacitor, but a paraelectric capacitor can be used.

In the case of the 1T-1C operation, consideration is given to a memory cell constituted of a transistor Tr[1] and a ferroelectric capacitor C[1] indicated by hatched lines in FIG. 11. Writing in the ferroelectric capacitor C[1] can be carried out similar to that in the case of 2T-2C but setting only the WL[1] to High.

To read data, in place of comparing the ferroelectric capacitors C[1] and C[2] with each other in the 2T-2C mode, the ferroelectric capacitor C[1] and a dummy capacitor DC[2] connected to the bit line BL[2] are compared. In this case, all the transistors connected to the bit line BL[2] must be turned OFF. Amount of charges discharged from the ferroelectric capacitor C[1] and the dummy capacitor DC[2] are detected by the sensor amplifier (S/A) to read the data.

As described above, according to the embodiment, the lower electrode of the ferroelectric capacitor is formed to be hexagonal and arranged to be closely packed, and the staggered-electrode capacitor is formed by shifting the upper electrode from the lower electrode, whereby the capacitor array having an effective size smaller than the minimum feature size of lithography can be formed. Hence, it can be provided a semiconductor memory device capable of achieving a higher packing density of the capacitors.

Various modifications and changes can be made to the embodiment. Some examples will be described below.

(Modification 3)

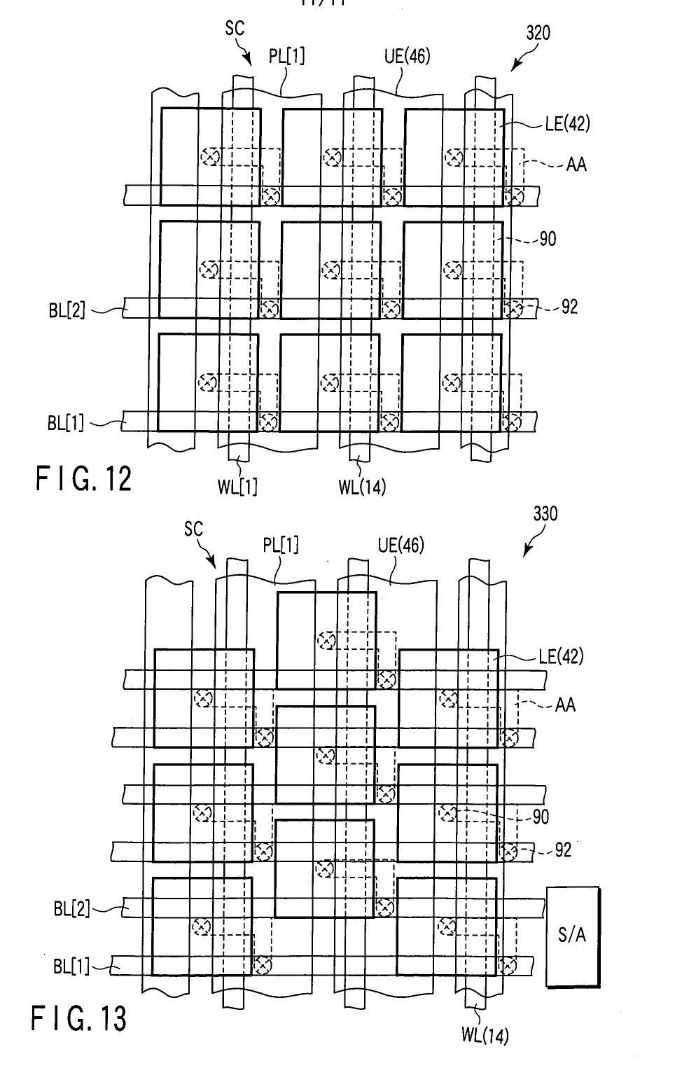

FIG. 12 is a plan diagram showing a semiconductor memory device 320 according to Modification 3. As shown in FIG. 12, the Modification is directed to the semiconductor memory device 320 having a structure, in which lower electrodes LE(42) are patterned into square shapes and arranged in a lattice, and the pair of word lines WL[1] and WL[2] are made common in the semiconductor memory device 300 of the third embodiment. As described above with reference to FIGS. 9A to 9C, in the case of the 2T-2C operation, the word lines WL[1] and WL[2] can be made common as their operations are always the same. In the case of the semiconductor memory device of the Modification, as shown in FIG. 12, close packing is achieved by forming a lower electrode 42 of a ferroelectric capacitor into a square shape not to a hexagonal shape.

The semiconductor memory device of the Modification allows the 2T-2C operation. However, even if a 1T-1C operation is being carried out, transistors Tr[1] and Tr[2] connected to a pair of bit lines BL[1] and BL[2] are simultaneously turned ON, thereby enabling the 1T-1C operation.

(Modification 4)

FIG. 13 is a plan diagram showing a semiconductor memory device 330 according to Modification 4. As shown in FIG. 13, the Modification is directed to the semiconductor memory device 330 having a structure similar to the third embodiment in which the shape of the lower electrode is made into a square shape. By arranging two rows of ferroelectric capacitors arrayed in a direction of a word line WL to be shifted from each other by a ½ pitch, it can be provided a semiconductor memory device capable of performing both of 2T-2C and 1T-1C operations.

As described above, according to the present invention, the staggered-electrode capacitor is formed by shifting the upper electrode from the lower electrode of the ferroelectric capacitor, whereby the capacitor array having an effective size smaller than a minimum feature size of lithography can be formed. Thus, it can be provided a semiconductor memory device capable of achieving a higher packing density of the capacitor.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a transistor including a gate electrode formed on a gate insulator on a semiconductor substrate and a plurality of sources/drains disposed in the semiconductor substrate to face each other holding the gate electrode therebetween;
a ferroelectric capacitor formed above the transistor and including a lower electrode, a ferroelectric film, and an upper electrode;
a first wiring line electrically connected to the lower electrode; and
a second wiring line electrically connected to the upper electrode,
wherein the ferroelectric capacitor is a staggered-electrode capacitor in which the upper electrode is shifted from the lower electrode and equivalently overlaps with parts of the plurality of lower electrodes.

2. The semiconductor memory device according to claim 1, further comprising:
a first cross point transistor electrically connecting the lower electrode to the first wiring line; and
a second cross point transistor electrically connecting the upper electrode to the second wiring line.

3. The semiconductor memory device according to claim 2, wherein
the first cross point transistor is formed below the staggered-electrode capacitor, and
the second cross point transistor is formed above the staggered-electrode capacitor.

4. The semiconductor memory device according to claim 2, wherein the first and second cross point transistors are formed above the staggered-electrode capacitor.

5. The semiconductor memory device according to claim 2, wherein the first and second cross point transistors are formed below the staggered-electrode capacitor.

6. The semiconductor memory device according to claim 1, wherein
the gate electrode of the transistor connects gate electrodes of the plurality of transistors arrayed in one direction in common and serves as a third wiring line,
the lower electrode is arranged to be close-packed in plane, and electrically connected through the transistor to the first wiring line disposed to be orthogonal to the third wiring line, and
the upper electrode overlaps with each one half of lower electrodes in two adjacent rows arrayed in a direction of the third wiring line, and is formed above the two rows of the lower electrodes in common to serve as the second wiring line.

7. The semiconductor memory device according to claim 6, wherein each row of the lower electrodes in the two rows is arranged to be shifted from each other in a direction of the third wiring line.

8. The semiconductor memory device according to claim 7, wherein the lower electrode is hexagonal.

9. The semiconductor memory device according to claim 8, wherein at least one edge of the ferroelectric capacitor has a size smaller than a minimum feature size of lithography used.

10. The semiconductor memory device according to claim 7, wherein the lower electrode is square.

11. The semiconductor memory device according to claim 6, further comprising:
a sense amplifier connected to one end of a pair of first wiring lines; and
a dummy capacitor electrically connected to the other end of the first wiring line.

12. The semiconductor memory device according to claim 11, wherein the lower electrode is hexagonal.

13. The semiconductor memory device according to claim 6, wherein the lower electrode is square.

14. The semiconductor memory device according to claim 1, wherein at least one edge of the ferroelectric capacitor has a size smaller than a minimum feature size of lithography used.

15. The semiconductor memory device according to claim 14, further comprising:
a first cross point transistor electrically connecting the lower electrode to the first wiring line; and
a second cross point transistor electrically connecting the upper electrode to the second wiring line.

16. The semiconductor memory device according to claim 14, wherein
the gate electrode of the transistor connects gate electrodes of the plurality of transistors arrayed in one direction in common and serves as a third wiring line,
the lower electrode is arranged to be close-packed in plane, and electrically connected through the transistor to the first wiring line disposed to be orthogonal to the third wiring line, and
the upper electrode overlaps with each one half of lower electrodes in two adjacent rows arrayed in a direction of the third wiring line, and is formed above the two rows of the lower electrodes in common to serve as the second wiring line.

17. A semiconductor memory device comprising:
a plurality of transistors electrically connected in series, each transistor including a gate electrode formed on a gate insulator on a semiconductor substrate and a plurality of sources/drains disposed in the semiconductor substrate to face each other holding the gate electrode therebetween;
a plurality of ferroelectric capacitors electrically connected to the transistors in parallel, each capacitor including a lower electrode, a ferroelectric film, and an upper electrode;
a first wiring line connected to one end of the plurality of serially connected transistors; and
a second wiring line connected to the other end of the plurality of serially connected transistors, wherein
the ferroelectric capacitors are staggered-electrode capacitors in which the lower and upper electrodes are square, arranged to be shifted from and overlapped with each other, and equivalently shared with a plurality of ferroelectric capacitors, and
a serial connection direction of the transistors is one of diagonal directions of the square lower and upper electrodes.

18. The semiconductor memory device according to claim 17, wherein at least one edge of the ferroelectric capacitor has a size smaller than a minimum feature size of lithography used.

19. The semiconductor memory device according to claim 17, wherein
the lower electrode is connected to one source/drain of the transistor and shared with two ferroelectric capacitors, each of the ferroelectric capacitors being disposed in parallel to one of two transistors connected with the source/drain, and
the upper electrode is connected to the other source/drain of the transistor and shared with two ferroelectric capacitors, each of the ferroelectric capacitors being disposed in parallel to one of two transistors connected with that other source/drain.
